(19) United States
(12) Patent Application Publication
(10) Pub. No.: US 2010/0220452 A1
(43) Pub. Date: Sep. 2, 2010

(54) OPERATING PANEL FOR AN ELECTRICAL APPLIANCE

(75) Inventor: Alfred Raab, Huttlingen (DE)

Correspondence Address: BSH HOME APPLIANCES CORPORATION;INTELLECTUAL PROPERTY DEPARTMENT, 100 BOSCH BOULEVARD, NEW BERN, NC, 28562, US

(73) Assignee: BSH BOSCH UND SIEMENS HAUSGERÄTE GMBH, Munich (DE)

(21) Appl. No.: 12/682,784

(22) PCT Filed: Oct. 15, 2008
(86) PCT No.: PCT/EP2008/063818

§ 371 Date: Apr. 13, 2010

(30) Foreign Application Priority Data
Oct. 26, 2007 (DE) 10 2007 051 335.8

(51) Int. Cl. H05K 5/00

(52) U.S. Cl. 361/752

(57) ABSTRACT

An operating panel for an electrical appliance that includes a receiving compartment open at least on one side thereof and an electronic circuit board. The electronic circuit board may be introduced by way of the at least one open side and fixed in the receiving compartment by fixing elements. In an exemplary embodiment of the invention, at least one side wall of the receiving compartment includes at least a first spring tongue, the first spring tongue intersecting a mounting plane for the electronic circuit board defined by the fixing elements.

The present invention relates to an operating panel for an electrical appliance, for example for a refrigeration appliance.

Modern large electrical appliances, such as refrigeration appliances, cookers and the like, in particular those designed to be freestanding, generally have a cuboid housing, to the front of which a door is attached. An operating panel is housed in a narrow cutout in the front above the door and accommodates a number of operating elements, such as switches, regulators and display elements, for operating the appliance and for displaying a current operating state. An electronic circuit board is mounted in an internal part of the operating panel to operate the operating elements.

However since the number of operating elements varies depending on the model of domestic appliance and its functional scope, different electronic circuit boards are also required, which not only vary in respect of the number of electronic components accommodated thereon but are also therefore of different sizes.

An operating panel for an electrical appliance is known from the unexamined German patent application DE 100 37 250 A1, in which different control circuits, each accommodating an electronic circuit board of a different size in a receiving compartment intended for the purpose on the electronic circuit board, also have specifically tailored adapters and are inserted into the operating panel in such a manner as to allow a number of assembly positions for the control circuit. However this has the disadvantage that a suitable receiving compartment and a suitable adapter are required for every model with a specific electronic circuit board in the control circuit with the result that a plurality of components have to be stocked for different appliance models.

The object of the present invention is therefore to specify an operating panel, with which electronic circuit boards of different sizes can be used for different appliance models without adapting the components holding the electronic circuit board.

The object is achieved by an operating panel for an electrical appliance comprising a receiving compartment, which is open on one side, into which an electronic circuit board can be introduced by way of the open side and can be fixed in a supported manner to support surfaces facing the open side, with at least one side wall of the receiving compartment holding at least a first spring tongue, which intersects a mounting plane for the electronic circuit board defined by the support surfaces. The electronic circuit board can thus be inserted very easily into the receiving compartment, as the support surfaces form a stop for a defined mounting plane of a carrier plate of the circuit board. A large electronic circuit board, which occupies the space in the interior of the operating panel taken by the first spring tongue in its relaxed state, can simply push the spring tongue to the side. In the case of an electronic circuit board which does not occupy this space, the spring tongue can serve as a stop, which determines the position of the electronic circuit board in the interior despite the small dimensions of this latter.

More precisely it is advantageous that, if the electronic circuit board exceeds a certain size and the electronic circuit board is fixed in the receiving compartment, the first spring tongue is deflected by an edge of the electronic circuit board parallel to the wall holding it. Because the first spring tongue can be sunk into the wall by the edge of the electronic circuit board, it can allow a larger electronic circuit board to be mounted, as the first spring tongue does not block the edge of the electronic circuit board.

If on the other hand the electronic circuit board fixed in the receiving compartment has a smaller format, it is advantageous if an edge of the electronic circuit board aligned transverse to the wall holding the first spring tongue is blocked by the first spring tongue. The first spring tongue can then project out of the wall and form a lateral stop for the electronic circuit board. If necessary, a number of stop positions can be formed by the arrangement of a number of first spring tongues at specified intervals along the mounting plane of the electronic circuit board, it being possible for these stop positions to be sunk into the wall by the edge of the circuit board or to block a lateral edge of the circuit board, depending on the size of the electronic circuit board.

To mount the electronic circuit board in the receiving compartment, it is advantageous if the first spring tongue is connected to the wall between the mounting plane and the open side. It is thus possible to insert the electronic circuit board into the receiving compartment from the open side without the aid of tools, without the first spring tongue forming an obstacle. For this purpose the spring tongue preferably projects from the wall without a step, which could form an obstacle for insertion of the electronic circuit board.

For solid mounting of the electronic circuit board at least one wall of the receiving compartment advantageously holds at least a second spring tongue, which is connected to the wall between the mounting plane and the open side and has a free end facing the mounting plane. During insertion of the electronic circuit board into the receiving compartment the second spring tongue can first recede into a plane of the wall. As soon as the electronic circuit board reaches its mounting plane and rests against the support surfaces, the second spring tongue can project from the open side by way of the lower edge of the carrier plate and latch this latter into a stop position. A number of second spring tongues can preferably be disposed on both an upper and lower wall, so that the electronic circuit board can be latched firmly from a number of sides.

To tailor the operating panel to different appliance models in a simple manner, it is also particularly advantageous if a décor plate covers a front face of the receiving compartment. Thus for different electronic circuit boards, which determine the respective functional scope of the appliance model, a décor plate with operating elements corresponding to the functional scope of the appliance can be positioned on the receiving compartment, so that it is not necessary to tailor the receiving compartment specifically to the appliance model.

Further features and advantages of the invention will emerge from the description which follows of exemplary embodiments with reference to the accompanying figures, in which:

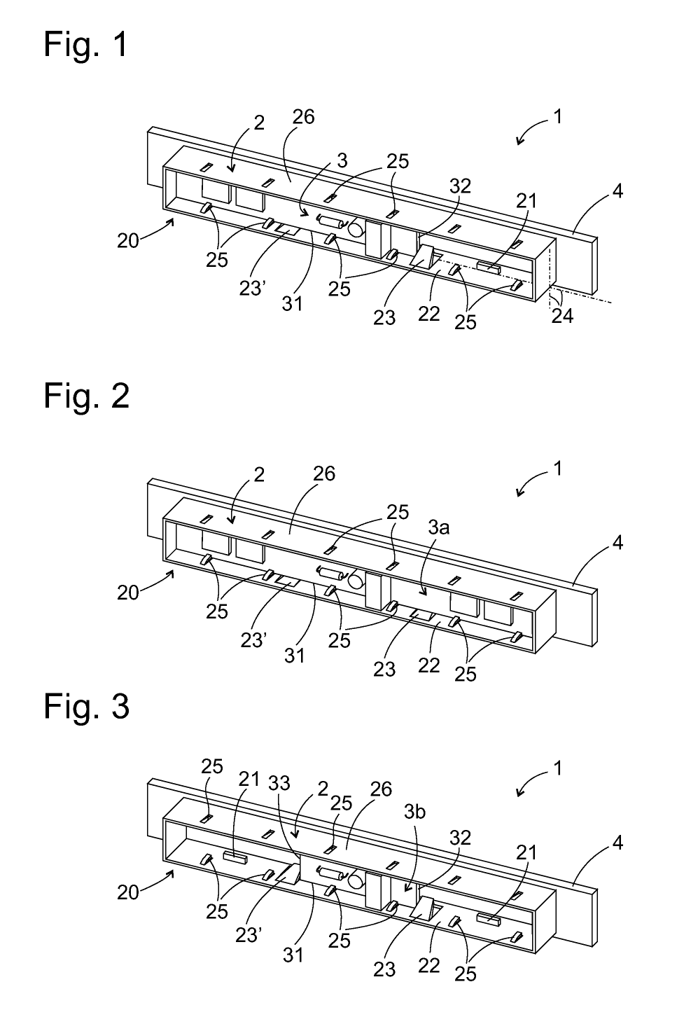

FIG. 1 shows a simplified diagram of an operating panel according to the invention having a mounted first electronic circuit board, viewed from the rear.

FIG. 2 shows the diagram from FIG. 1, a second longer electronic circuit board being mounted; and

FIG. 3 shows the diagram from FIG. 1, a third shorter electronic circuit board being mounted.

FIG. 1 shows a simplified diagram of an operating panel 1 for an electrical appliance, viewed obliquely from the rear. The operating panel 1 is provided for mounting on a front face of the electrical appliance above a door.

The operating panel 1 comprises a narrow, longitudinally extended frame 4, a receiving compartment 2, which has a longitudinally extended cuboid shape, and a first electronic circuit board 3 holding a number of electronic components, said electronic circuit board 3 being mounted in the receiving compartment 2. The frame 4 is open at its front face facing away from the observer in FIG. 1; a décor plate (not shown) having windows or through holes for operating and display elements of the electronic circuit board 3, which is specific to the model of the electrical appliance and is familiar to the person skilled in the art from DE 100 37 250 A1, closes off the front face of the frame 4.

The receiving compartment 2 has four side walls, which stand out in a perpendicular manner from a rear face of the frame 4 and an open rear face 20 bounded by the side walls, through which the first electronic circuit board 3 can be inserted for mounting in the receiving compartment 2. The first electronic circuit board 3 takes up roughly two thirds of the length of the receiving compartment 2 and rests against inner surfaces of the side walls of the receiving compartment 2 along three edges.

The upper and lower side walls 26 and 22 of the receiving compartment each hold a number of narrow, rib-type support surfaces 21 on their inner faces, these support surfaces 21 projecting in a perpendicular manner into an interior of the receiving compartment 2 and being disposed parallel to a rear edge of the side wall 22 bounding the rear face 20, forming a front stop for the first electronic circuit board 3 so that the support surfaces 21 define a mounting plane 24 of the first electronic circuit board 3. Even though FIG. 1 only shows one of the support surfaces 21 on the lower side wall 22, it can easily be comprehended that support surfaces covered by the first electronic circuit board 3 must be present on the side walls 26, 22 in sufficient numbers or of suitable shape and extension to define the position of the circuit board 3 uniquely.

A first spring tongue 23 is also disposed on the lower side wall 22, being connected to the side wall 22 close to the rear edge of the side wall 22 and standing out from there obliquely upward from the side wall 22 into the interior of the receiving compartment 2. In this process the first spring tongue 23 intersects the mounting plane 24 of the first electronic circuit board 3. The first spring tongue 23 can be deflected toward the side wall 22, it being possible for the first spring tongue 23 to recede completely into the side wall 22 in an opening in the side wall 22 corresponding to its shape. Since in its relaxed position the first spring tongue 23 intersects the mounting plane 24, the first spring tongue 23 blocks a lateral edge 32 of the first electronic circuit board 3, so that the latter is held firmly in its mounting position at all four edges.

In FIG. 1 a further first spring tongue 23′ is partially visible, being deflected by a lower edge 31 of the first electronic circuit board 3 and receding into the side wall 22 completely. The first spring tongues 23, 23′ are positioned along the mounting plane 24 in such a manner that they divide the side wall 22 into three segments of approximately equal length.

From the rear face 20 of the receiving compartment 2 the first electronic circuit board 3 is held by a number of second spring tongues 25 disposed on the side walls 22, 26, it being possible for these second spring tongues 25 in a relaxed position also to project from the side wall 22 or 26 into the interior of the receiving compartment 2 and to be deflected in a flexible manner so that they recede into correspondingly shaped recesses in the side wall 22 or 26. The second spring tongues 25 are also connected to the side wall 22 or 26 close to the rear edge. A free end of the second spring tongues 25 faces the mounting plane 24 of the first electronic circuit board 3 and forms a rear stop for the mounting position of the first electronic circuit board 3.

When the first electronic circuit board 3 has been inserted into the receiving compartment 2, the second spring tongues 25 are first deflected by the lower edge 31 or upper edge of the electronic circuit board 3 and recede into the side wall 22, 26. Once the first electronic circuit board 3 reaches its mounting position, the second spring tongues 25 spring back into their relaxed position, so the electronic circuit board 3 is firmly latched.

FIG. 2 shows the same receiving compartment as in FIG. 1, with a second electronic circuit board 3a mounted instead of the first electronic circuit board 3 and taking up the entire length of the receiving compartment 2.

The first spring tongue 23 is also deflected from its base position by the second electronic circuit board 3a and is sunk into the side wall 22 to allow the longer electronic circuit board 3a to be mounted. All the support surfaces 21 are covered by the second electronic circuit board 3a in this diagram.

The diagram in FIG. 3 shows the receiving compartment 2 with a third electronic circuit board 3b mounted, which only takes up around a third of the length of the receiving compartment 2 and rests with an upper and lower edge against the inner surfaces of the lower side wall 22 and the upper side wall 26. The lateral edge 32 and an opposing lateral edge 33 are respectively blocked by one of the first spring tongues 23, 23′, which stand out from the side wall 22 in their relaxed position.

In order to achieve even greater flexibility for mounting electronic circuit boards of different sizes in the receiving compartment 2, in further embodiments of the invention it is possible to change the number of first spring tongues 23, 23′ and their positions along the mounting plane 24. One or a number of first spring tongues 23, 23′ can also be disposed on the upper side wall 26. Depending on the arrangement of the first spring tongues 23, 23′, it is also possible to vary the number and arrangement of the support surfaces 21 along the mounting plane 24.

1-10. (canceled)

11. An operating panel for an electrical appliance, the operating panel comprising:
a receiving compartment open at least on one side thereof;
an electronic circuit board, the electronic circuit board operable to be introduced by way of the at least one open side and fixed in the receiving compartment by fixing elements, wherein
at least one side wall of the receiving compartment includes at least a first spring tongue, the first spring tongue intersecting a mounting plane for the electronic circuit board defined by the fixing elements.

12. The operating panel as claimed in claim 11, wherein the fixing elements are retaining lugs.

13. The operating panel as claimed in claim 11, wherein the fixing elements are support surfaces.

14. The operating panel as claimed in claim 11, wherein the first spring tongue is deflected by an edge of the electronic circuit board parallel to the at least one side wall when the electronic circuit board is fixed in the receiving compartment.

15. The operating panel as claimed in claim 11, wherein the electronic circuit board is fixed in the receiving compartment and an edge of the electronic circuit board aligned transverse to the at least one side wall is blocked by the first spring tongue.

16. The operating panel as claimed in claim 11, wherein the first spring tongue is connected to the at least one side wall between the mounting plane and the at least one open side.

17. The operating panel as claimed in claim 11, wherein the at least one side wall holds at least a second spring tongue, which is connected to the at least one side wall between the mounting plane and the at least one open side and has a free end facing the mounting plane.

18. The operating panel as claimed in claim 11, further comprising a décor plate covering a front face of the receiving compartment.

19. A domestic appliance comprising an operating panel, the operating panel comprising:
a receiving compartment open at least on one side thereof;
an electronic circuit board, the electronic circuit board operable to be introduced by way of the at least one open side and fixed in the receiving compartment by fixing elements, wherein
at least one side wall of the receiving compartment includes at least a first spring tongue, the first spring tongue intersecting a mounting plane for the electronic circuit board defined by the fixing elements.

20. The domestic appliance as claimed in claim 19, wherein the domestic appliance is a refrigeration appliance.
